(19) United States
(12) Patent Application Publication
(10) Pub. No.: US 2026/0068591 A1
(43) Pub. Date: Mar. 5, 2026

(54) SUBSTRATE ALIGNER MECHANISM IN VACUUM FLIPPER MODULE

(71) Applicant: Applied Materials, Inc., Santa Clara, CA (US)

(72) Inventors: Sathiyamurthi GOVINDASAMY, Coimbatore (IN); Puviyarasu PALANISAMY, Bangalore (IN); Raju BRIJESH, Santa Clara, CA (US); Suresh PALANISAMY, Coimbatore (IN); Dinesh RAJAMANICKAM, Coimbatore (IN); Karunakaran NATARAJ, Coimbatore (IN); Suyamburaj SUBBUDURAI, Coimbatore (IN)

(21) Appl. No.: 18/821,379

(22) Filed: Aug. 30, 2024

(51) Int. Cl. H01L 21/68; H01L 21/687

(52) U.S. Cl. CPC H01L 21/68

(57) ABSTRACT

In one embodiment, a module of a processing system is provided. The module of a processing system, includes a clamp assembly, and an alignment mechanism. The clamp assembly includes a first plate with a first inner surface and a first outer surface disposed opposite the first inner surface, and a second plate disposed about parallel to the first plate. The second plate includes a second inner surface facing the first inner surface of the first plate. The alignment mechanism includes a profile rod coupled to the second plate and a follower assembly coupled to the first plate. The follower assembly includes a connection element coupled to the first plate, a follower roller biased toward the profile rod, and an arm extending from the first plate toward the second plate, the arm includes an alignment roller disposed between the first plate and the second plate.

### BACKGROUND

### Field

Embodiments of the present disclosure generally relate to apparatus and methods of processing substrates in an electronic device fabrication system, and more particularly, to apparatus and methods for flipping substrates in vacuum between deposition processes performed on opposing sides of a substrate.

### Description of the Related Art

Substrate processing in electronic device fabrication often involves performing a deposition process on both sides of a substrate. However, process chambers are typically designed for depositing material on only one surface at a time, such as on the upper or lower surface of the substrate. Therefore, it is often necessary to flip or re-reorient the substrate in relation to the chamber between deposition processes.

This is a particular challenge when processing some large-area substrates, such as panels. For example, a common panel size may be 600 mm by 600 mm. Common panel materials can include Ajinomoto Build-up Film (ABF), Copper Clad Laminate (CCL), panel with polymer on top, glass, etc. Because of the large surface area of the polymer material on the panels, the panels absorb a lot of moisture. Therefore, to achieve good contact resistance a very efficient de-gas is required to remove all outgassing from the panels and remove contamination.

In order to perform physical vapor deposition (PVD) sputtering on both sides of a substrate/panel, in conventional designs the substrate/panel is removed from vacuum and flipped in atmosphere. When the substrate/panel is removed from vacuum, an additional degassing operation is required to remove moisture absorbed on the substrate/panel. Since degassing can take tens of minutes, such as about 40 minutes in some cases, this additional degassing operation very negatively affects panel throughput.

There have been attempts to hold substrates/panels vertically in the PVD chamber in order to sputter from both sides simultaneously. However, with this approach, there is no active cooling to the substrate/panel and undesirable arcing can occur, which can damage the panel.

Accordingly, there is a need in the art for apparatus and methods for maintaining alignment when flipping substrates/panels in vacuum between deposition steps performed on each side of a panel.

### SUMMARY

Embodiments described herein generally relate to dual sided physical vapor deposition (PVD) sputtering of substrates in an electronic device fabrication process. More particularly, embodiments described herein provide apparatus and methods for aligning and flipping substrates in vacuum between performing manufacturing operations on each side.

In one embodiment, a module of a processing system is provided. The module of a processing system, includes a clamp assembly, and an alignment mechanism. The clamp assembly includes a first plate with a first inner surface and a first outer surface disposed opposite the first inner surface, and a second plate disposed about parallel to the first plate. The second plate includes a second inner surface facing the first inner surface of the first plate. The alignment mechanism includes a profile rod coupled to the second plate and a follower assembly coupled to the first plate. The follower assembly includes a connection element coupled to the first plate, a follower roller biased toward the profile rod, and an arm extending from the first plate toward the second plate, the arm includes an alignment roller disposed between the first plate and the second plate.

In another embodiment, a flipper module of a processing system is provided. The flipper module includes a clamp assembly, a flipping axis, a first alignment mechanism, and a second alignment mechanism. The clamp assembly includes a first plate and a second plate. The first plate has a first inner surface, and a first outer surface disposed opposite the first inner surface. The second plate is disposed about parallel to the first plate. The second plate includes a second inner surface facing the first inner of the first plate. The first plate and the second plate define a substrate receiving region therebetween. The flipping axis is disposed between the first plate and the second plate. The clamp assembly is configured to rotate about the flipping axis. The first alignment mechanism includes a profile rod coupled to the second plate and extending toward the first plate, and a follower assembly coupled to the first plate. The follower assembly includes a connection element coupled to the second plate, a follower roller biased toward the profile rod, and an arm extending past the first outer surface of the first plate and extending toward the second plate. The arm includes an alignment roller disposed between the first plate and the second plate. The second alignment mechanism disposed across the substrate receiving region from the first alignment mechanism, the first alignment mechanism and the second alignment mechanism configured to actuate towards the substrate receiving region when the first plate and the second plate are moved from a receiving state to a clamped state.

In another embodiment, a module of a processing system is provided. The module includes a clamp assembly, a receiving region separating a first actuation region and a second actuation region, and a lift pin plate assembly. The lift pin plate assembly includes a lift pin plate, a plurality of lift pins that extend toward the clamp assembly, and one or more alignment mechanisms. Each alignment mechanism of the one or more alignment mechanisms includes a motor coupled to the lift pin plate, a shaft disposed perpendicular to the lift pin plate, a rotation plate extending from the shaft, a first arm extending from the rotation plate and away from the motor, the first arm coupling a first alignment roller to the rotation plate, and a second arm extending from the rotation plate and away from the motor, the second arm disposed farther from the shaft than the first arm, the second arm coupling a second alignment roller to the rotation plate, the first arm disposed between the shaft and the second arm.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic top view of an exemplary substrate processing system, according to certain embodiments.

FIG. 2 is a diagram illustrating a method of flipping a substrate in vacuum using a flipper module, according to certain embodiments.

FIG. 3A is a schematic top isometric view of a portion of the substrate processing system of FIG. 1 including a flipper module, according to certain embodiments.

FIG. 3B is a schematic top isometric view of a portion of the substrate processing system of FIG. 1 including the flipper module, according to certain embodiments.

FIG. 4 is partial side cross-sectional view of the flipper module in the clamped state, according to certain embodiments.

FIG. 5A is partial side cross-sectional view of the flipper module in the open position, according to certain embodiments.

FIG. 5B is a partial exploded view of a clamp assembly according to certain embodiments.

FIG. 6 is an isometric view of an alignment mechanism according to certain embodiments.

FIG. 7A is an isometric view of an alignment mechanism according to some embodiments.

FIG. 7B is top view of the alignment mechanism in FIG. 7A according to some embodiments.

FIG. 7C is an isometric view of the alignment mechanism in FIG. 7A according to some embodiments.

FIG. 8A is an isometric view of an alignment mechanism according to some embodiments.

FIG. 8B is top view of the alignment mechanism according to some embodiments.

FIG. 8C is top view of the alignment mechanism according to some embodiments.

FIG. 9A is an isometric view of an alignment mechanism 900 according to some embodiments.

FIG. 9B is top view of the alignment mechanism 900 according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to dual sided physical vapor deposition (PVD) processes performed on substrates in an electronic device fabrication system. More particularly, embodiments described herein provide apparatus and methods for flipping substrates in vacuum between PVD processes, such as sputtering, on each side of a substrate.

Embodiments described herein enable the ability to deposit a material on both sides of a substrate without removing the substrate from vacuum, in contrast to conventional approaches in which the substrates are removed from vacuum and flipped in atmosphere. Performing this process in vacuum eliminates an additional degassing operation and increases throughput.

Embodiments described herein have the ability to deposit a material on both sides of a substrate without holding the substrate vertically. Performing a sputtering process on a substrate that is positioned flat and horizontally on a substrate support enables active cooling and prevents undesirable arcing. Embodiments described herein provide apparatus for flipping and aligning substrates in vacuum within a load lock chamber without increasing a footprint of either existing or new processing systems. Embodiments described herein enable flipping of large area substrates in vacuum in addition to conventional substrates.

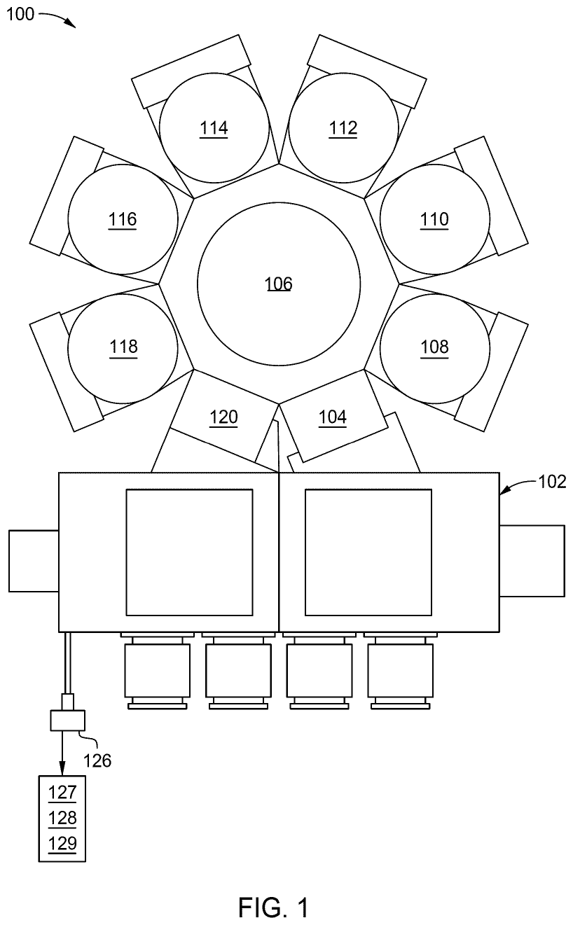

FIG. 1 is a schematic top view of an exemplary substrate processing system 100 (also referred to as a “processing platform”), according to certain embodiments. In certain embodiments, the substrate processing system 100 is particularly configured for processing large-area substrates. As used herein, the term “panel” may refer to a large-area substrate that can be used in the formation of device packages or large panel displays. In some device packaging examples, a “panel” may include a large surface area substrate that includes a polymer material disposed over a structural core. The substrate processing system 100 generally includes an equipment front-end module (EFEM) 102 for loading substrates into the processing system 100, a first load lock chamber 104 coupled to the EFEM 102, a transfer chamber 106 coupled to the first load lock chamber 104, and a plurality of other chambers coupled to the transfer chamber 106 as described in detail below. Proceeding counterclockwise around the transfer chamber 106 from the first load lock chamber 104, the processing system 100 includes a first dedicated degas chamber 108, a first pre-clean chamber 110, a first deposition chamber 112, a second pre-clean chamber 114, a second deposition chamber 116, a second dedicated degas chamber 118, and a second load lock chamber 120. The second load lock chamber 120 includes a flipper module for flipping a substrate in vacuum. As used herein, the term “vacuum” may refer to pressures below about 10⁻² Pa. However, some high-vacuum systems may operate below 10⁻⁷ Pa.

In certain embodiments a system controller 126, also referred to herein as a processing chamber controller, includes a central processing unit (CPU) 127, a memory 128, and support circuits 129. The system controller 126 is used to control a process sequence when processing the substrate 122, including the substrate transferring and substrate flipping methods described herein. The CPU 127 is a general-purpose computer processor configured for use in an industrial setting for controlling the processing system 100 and sub-processors related thereto. The memory 128 described herein, which is generally non-volatile memory, may include random access memory, read-only memory, floppy or hard disk drive, or other suitable forms of digital storage, local or remote. The support circuits 129 are conventionally coupled to the CPU 127 and may comprise cache, clock circuits, input/output subsystems, power supplies, and the like, and combinations thereof. Software instructions (i.e., software program) and data can be coded and stored within the memory 128 for instructing a processor within the CPU 127. A software program readable by CPU 127 in the system controller 126 determines which tasks are performable by the components in the processing system 100. Typically, the software program, which is readable by CPU 127 in the system controller 126, includes code, which, when executed by the processor (CPU 127), performs tasks relating to the processing and substrate transfer schemes described herein. The software program may include instructions that are used to control the various hardware and electrical components within the processing system 100 so that the methods described herein can be performed. In one embodiment, the program includes instructions that are used to perform one or more of the methods of flipping and aligning a substrate described herein.

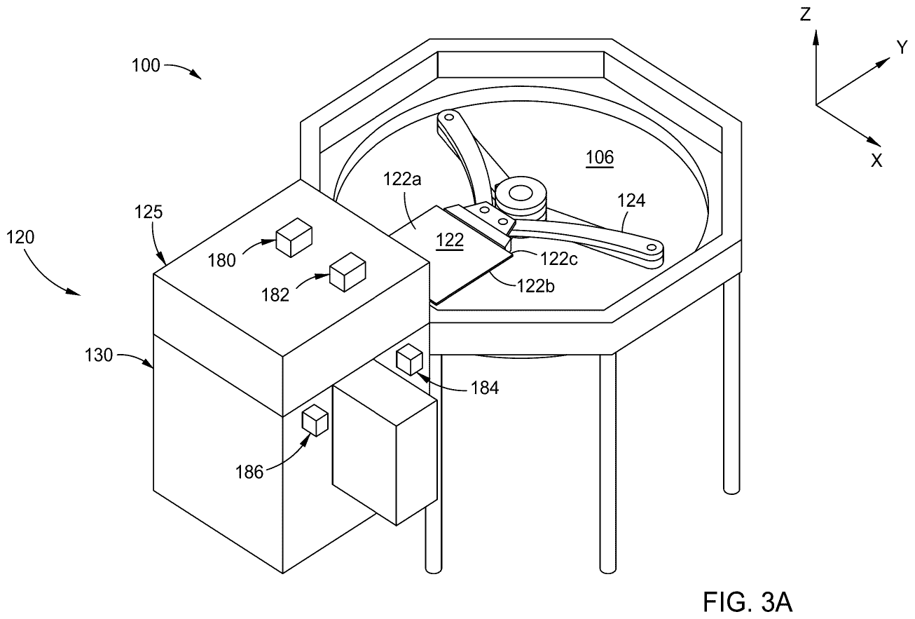

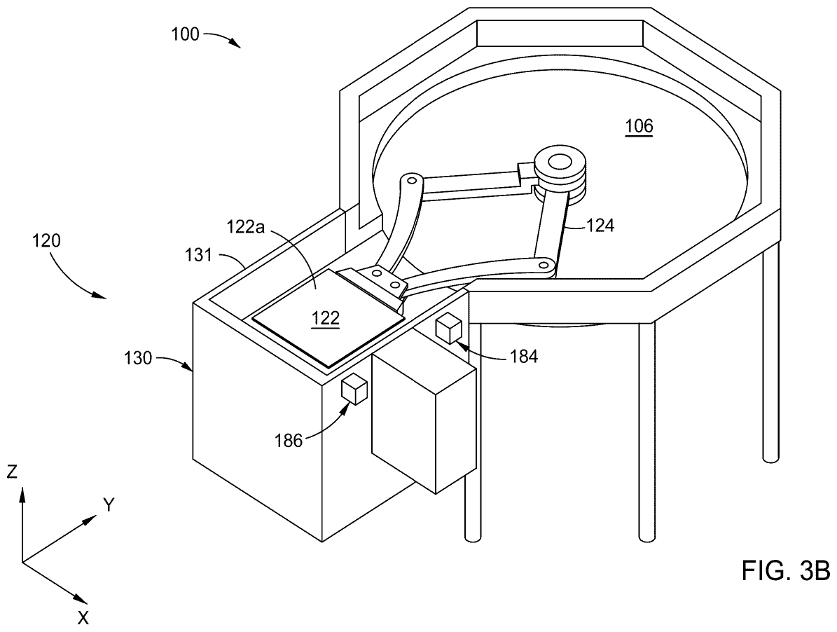

In certain embodiments, substrates are loaded into the processing system 100 through a door (also referred to as a “slit valve”), in the first load lock chamber 104 and unloaded from the processing system 100 through a door in the second load lock chamber 120. In certain embodiments, a stack of substrates is supported in a cassette, which is placed in the first load lock chamber 104. Once the first load lock chamber 104 is pumped down, one substrate at a time is retrieved from the cassette using a robot located in the transfer chamber 106. In one embodiment, the second load lock chamber 120 receives a single substrate after processing has been performed on each side and unloads the processed substrate to the EFEM 102. The second load lock chamber 120 may be a dual chamber including an upper chamber 125 (FIG. 3A) for receiving the substrate after both sides have been processed and unloading the substrate to the EFEM 102, and a lower portion including a flipper module 130 (FIG. 3A) for flipping a substrate having one side processed in order to process the other side. However, other loading and unloading configurations are also contemplated.

By performing pre-cleaning in the first and second pre-clean chambers 110, 114 that share the same vacuum environment as the first and second deposition chambers 112, 116, the substrates can be transferred from the cleaning chambers to the deposition chambers without being exposed to atmosphere. In certain embodiments, only one substrate is processed within each pre-clean and deposition chamber at a time. Alternatively, multiple substrates may be processed at one time, such as four to six substrates. In such embodiments, the substrates may be disposed on a rotatable pedestal within the respective chambers. In certain embodiments, the first and second deposition chambers 112, 116 are PVD chambers configured to deposit copper, titanium, aluminum, gold, nickel, nickel vanadium, silver, and/or tantalum.

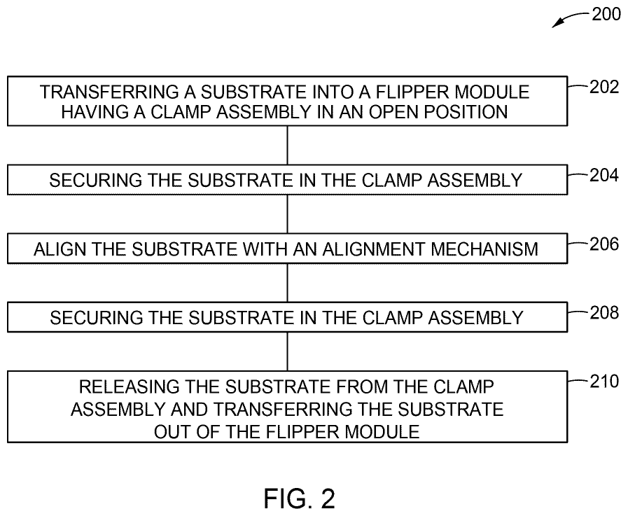

FIG. 2 is a diagram illustrating a method 200 of flipping a substrate 122 in vacuum using a flipper module 130 of the second load lock chamber 120, according to certain embodiments. As discussed below, the process of flipping a substrate may be performed between deposition processes performed on opposing sides of a substrate. Thus, by interleaving a flipping step between deposition steps on opposing sides of a substrate, a first side of a substrate can receive a deposited material, while the opposing second side of the substrate, which is opposite to the side receiving the deposited material, is supported by and actively cooled and/or biased by elements in the substrate supporting member in the deposition chamber.

FIG. 3A is a schematic top isometric view of a portion of the substrate processing system 100 illustrated in FIG. 1, according to certain embodiments. As shown, the load lock chamber 120 is configured to receive and unload a substrate 122 during processing and includes an upper chamber 125, and the flipper module 130 configured to receive a substrate 122 processed, for example, on a front side 122a and flip the substrate 122 for processing on the backside 122b.

As illustrated in FIG. 3A, a substrate 122 is disposed in the transfer chamber 106. Note that in FIG. 3A, only the transfer chamber 106 and the flipper module 130 of the second load lock chamber 120 are shown for clarity. An edge of the substrate 122c is in contact with an end effector of a transfer robot 124. The substrate 122 and the end effector of the transfer robot 124 are aligned with a door of the flipper module 130 of the load lock chamber 120. According to some embodiments, a front side 122a of the substrate 122 is facing upwards, and a backside 122b is facing down. The substrate 122 can have a thickness in a range from about 0.1 mm to about 4 mm, for example in a range from about 0.2 mm to about 3.2 mm. In the example, the substrate 122 is a panel (also referred to herein as a “substrate”).

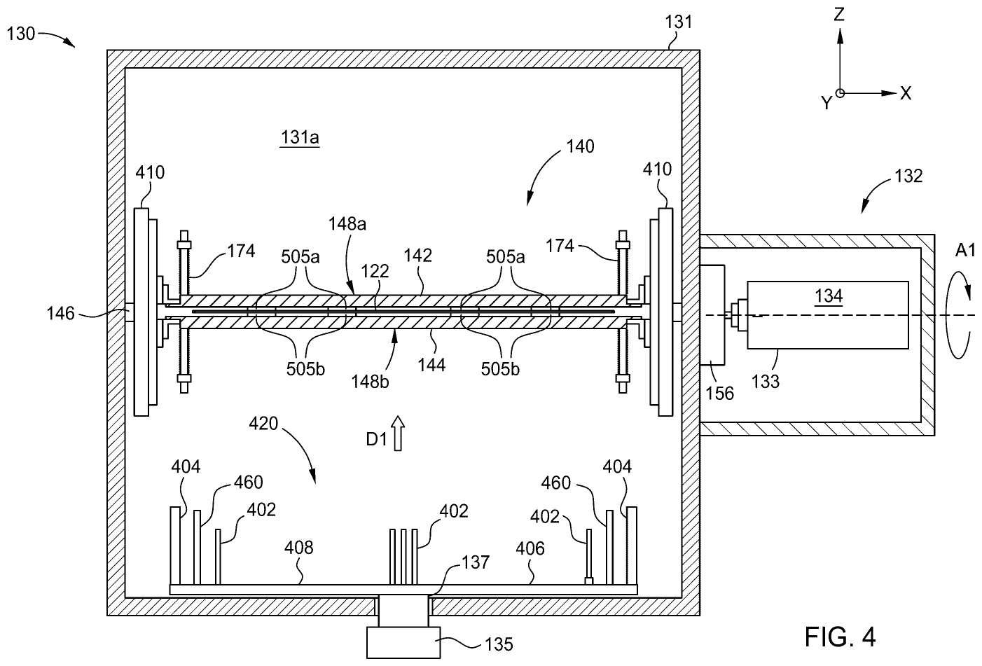

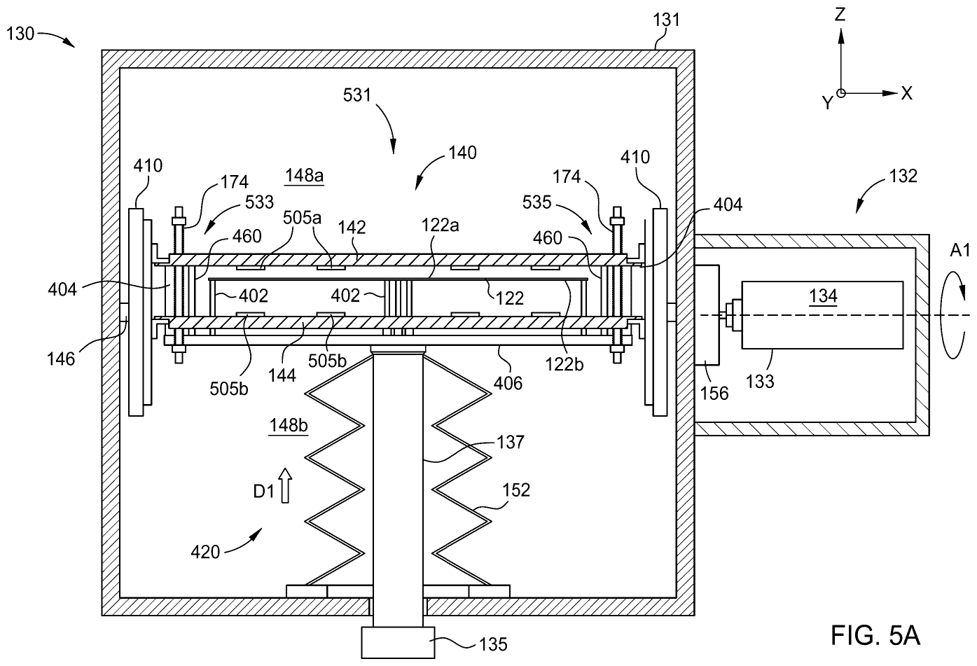

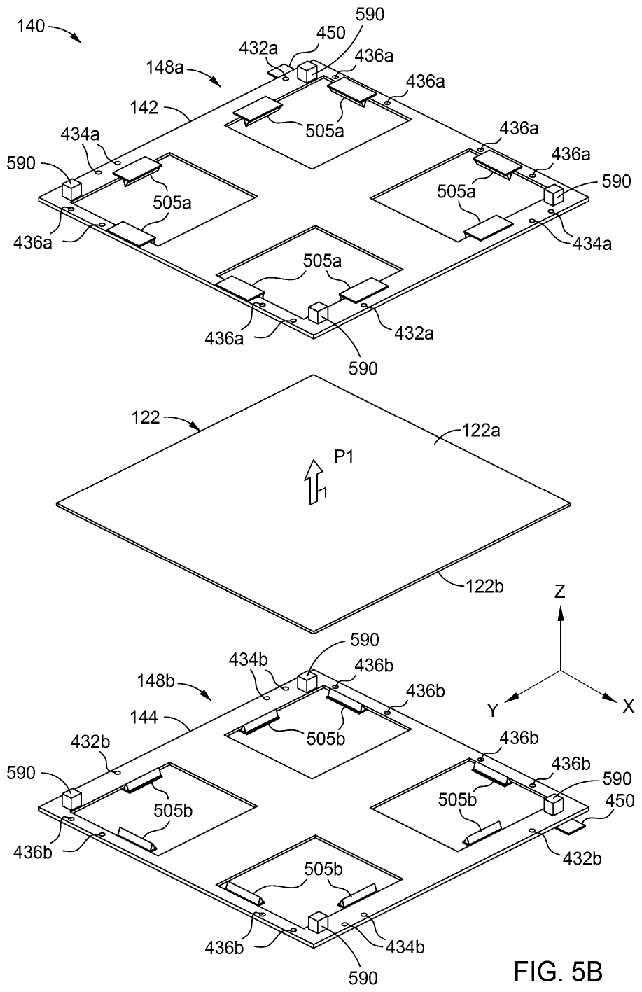

FIG. 3A further shows how the load lock chamber 120 also may include a plurality of sensors 180, 182, 184, 186. Each of the sensors 180, 182, 184, 186 of the plurality of sensors 180, 182, 184, 186 are optical sensors but may also be proximity, pressure, rotation, temperature, other sensors, or any combination thereof for analyzing the characteristics of the chamber 120 and substrate 122. According to some embodiments, a panel or substrate presence sensor 180 reads if a substrate 122 has been positioned within the chamber 120 or the flipper module 130. A panel or substrate transfer sensor 182 reads if a substrate 122 has been released by the transfer robot 124. A panel or substrate rotation sensor 184 reads how much the substrate 122 has been rotated during a flipping process, for example, the flipping process of FIG. 2 (described below). For context, the amount the substrate 122 has been rotated can indicate if the flipper module 130 is ready to perform another step in a flipping operation. A clamp position sensor 186 reads if a substrate 122 is currently secured by the flipper module 130 during a flipping process. The substrate is not secured when a clamp assembly 140, as shown in FIG. 4, is in an open position and the substrate 122 is secured when the clamp assembly 140, as shown in FIG. 5A, is in a clamped state. As shown in FIG. 3A, the plurality of sensors 180, 182, 184, 186 are positioned on the exterior of the chamber 120, but may be disposed within the chamber 120 in some embodiments. According to some embodiments the plurality of sensors 180, 182, 184, 186 may be connected to the controller 126 to monitor and control the flipper module 130.

FIG. 3B illustrates the substrate 122 once the transfer robot 124 transfers the substrate 122 from the transfer chamber 106 into the flipper module 130. Note that in FIG. 3B, only the transfer chamber 106 and the flipper module 130 of the second load lock chamber 120 are shown for clarity. Also, note that upper portion of the load lock chamber is omitted in order to illustrate an interior of each respective chamber. As shown in FIG. 3B, the transfer robot 124 has moved the substrate 122 from the transfer chamber 106 into a housing 131 of the flipper module 130. Once the substrate is in the flipper module 130 the transfer robot can release the substrate 122 and allow the flipper module 130 to provide support to the substrate 122.

FIG. 4 illustrates a schematic representation of the flipper module 130 that includes a housing 131, the clamp assembly 140, a motor assembly 134, and a lift pin plate assembly 420, according to some embodiments, in a clamped state (also referred to as a clamped position, closed position, or closed orientation), for rotation.

As shown in FIG. 4, the flipper module 130 illustrates the clamp assembly 140, which is held within vacuum environment 131a along with the lift pin plate assembly 420, while the motor assembly is disposed on an exterior of the module housing 131, and not within the vacuum environment 131a. According to some embodiments, the motor assembly 134 includes a housing 132, a motor 133 and a shaft and seal assembly 156. The motor 133 is a flipping motor configured to rotate the clamp assembly 140 around a flipping axis A1. In the clamped position, the lift pin plate assembly 420 is out of the rotational path of the clamp assembly 140. The rotation path of the clamp assembly 140 is formed about the flipping axis A1, by use of the motor assembly 134.

As illustrated in FIGS. 4 and 5A, the clamp assembly 140 includes a first clamp assembly 148a, a second clamp assembly 148b, at least one of two or more clamp sliders 410, and at least one of two or more spring-loaded connectors 174. The first clamp assembly 148a includes a first plate 142, and the second clamp assembly 148b includes a second plate 144. The first and second plates 142, 144 are held parallel to each other by the clamp sliders 410. The one or more clamp sliders 410 are meant to provide a link between the first plate 142 and the second plate 144 to help keep them parallel and also allow a mechanical bias force, provided by one of two or more spring-loaded connectors 174.

As shown in FIG. 4, the motor assembly 134 is connected to the clamp assembly 140 by the shaft and seal assembly 156. The shaft and seal assembly 156 is connected to at least one or more clamp sliders 410 through the module housing 131. A bearing 146 is coupled to the interior of the housing 131 to the clamp sliders 410 connected to the side of clamp assembly 140 side opposite the motor assembly 134. The bearing 146 is in line with the flipping axis A1 and supports the clamp assembly 140. The shaft and seal assembly 156 allow rotation motion to be transferred from the motor 133 to the clamp assembly 140 while maintaining a vacuum environment in the process system 100. As shown in FIG. 4, the flipping axis A1 is parallel to the X axis. The motor 133 may include programed stops every 180°and be an electric, gear drive, or belt drive motor assembly, but other types are contemplated.

As shown in FIG. 4, the lift pin plate assembly 420 includes a lift pin plate 406 coupled to an actuator 135 by the actuator shaft 137. The actuator 135 is coupled to the housing 131 of the flipper module 130. The actuator 135 extends and retracts the lift pin plate assembly 420 along a first direction D1 parallel to the Z-axis. The actuator axis is parallel to the Z-direction in the coordinate system of FIG. 4. The lift pin plate assembly 420 includes a plurality of lift pins 402 extending from a lift pin plate surface 408 and a plurality of clamp assembly pins 404 extending from the lift pin plate surface 408. Additionally, the lift pin plate assembly 420 may include a plurality of clamp alignment pins 460 extending, along the first direction D1, from the lift pin plate surface 408.

The lift pin plate assembly 420 includes the plurality of lift pins 402, the plurality of clamp assembly pins 404, and the plurality of clamp alignment pins 460 that are aligned in the first direction D1. During a flipping operation the lift pin plate 406 is lowered out of a rotational path of the clamp assembly 140 by the actuator 135. In some embodiments, the actuator is outside of the housing 131, at standard pressured while the actuator shaft 137 is disposed within the housing 131 and the actuator 135 and actuator shaft 137 are sealed by use of a bellows assembly 152 to prevent loss of vacuum pressure.

The plurality of lift pins 402 are configured to support and receive the substrate 122 when the actuator 135 extends the lift pin plate assembly 420 into the clamp assembly 140. As shown in FIG. 5A, the clamp assembly pins 404 are configured to contact and hold open the clamp assembly 140 when the actuator 135 extends the lift pin plate assembly 420 into the clamp assembly 140 as described in more detail below. The clamp alignment pins 460 are configured to align the clamp assembly 140 when the clamp alignment pins 460 pass through alignment apertures 436a-b, as seen in FIG. 5B. The clamp alignment pins 460 pass through alignment apertures 436a-b in the clamp assembly perpendicular to the first plane P1.

As shown in FIG. 4, the spring-loaded connectors 174 mechanically bias the first plate 142 and the second plate 144 of the clamp assembly towards a clamped state. The spring-loaded connectors 174 are coupled to the first and second clamp assemblies 148a, 148b. There are at least one or more clamp sliders 410 coupled to the clamp assembly 140. The clamp sliders 410 are coupled to the motor assembly 134 so the motor 133 transfers rotational energy to the clamp assembly 140 through the clamp slider 410. Another clamp slider 410 positioned opposite to the clamp slider 410 near the motor assembly 134, on the left side of FIG. 4, is coupled to the bearing 146 for support during rotation of the clamp assembly 140 as part of the performance of method 200. The bearing 146 is coupled to the interior of the flipper module 130.

As illustrated in FIG. 5A, when the clamp assembly 140 is in the open position the module is properly oriented to receive a substrate, or ready for a substrate to be removed from the clamp assembly 140.

The clamp assembly 140 is in the open position when the clamp assembly pins 404 of the lift pin plate assembly 420 are in contact with an opposing plate of the clamp assembly 140. As shown in FIG. 5A, the clamp assembly pins 404 work against the bias force of the spring-loaded connectors 174 to separate the opposing plate of the clamp assembly 140 from the substrate 122. The clamp assembly pins 404 contact the first plate 142, which is on an opposing side of the clamp assembly 140, and thus pass through the second plate 144 when the clamp assembly 140 is positioned in this orientation. As shown in FIG. 5A, the plurality of lift pins 402 pass through the first plate 142 or second plate 144 to contact and support the substrate 122. The first and second plates 142, 144 further comprise a plurality of apertures 432a-b, 434a-b, 436a-b, as seen in FIG. 5B. When in the open position, the clamp assembly pins 404 pass through apertures 432a-b, 434a-b depending on whether the first plate 142 or second plate 144 is closer to the lift pin plate assembly 420, due to its flipped orientation (e.g., which plate is on the top or bottom of the clamp assembly 140). In general, the first and second plate apertures 432a-b, 434a-b are configured so that the clamp assembly pins 404 will only contact the plate that is on the opposite side of the lift pin plate assembly 420. The plate apertures 432a-b, 434a-b of the plate nearer to the lift pin plate assembly 420 will allow the clamp assembly pins 404 to pass therethrough.

As seen in FIG. 5A, once the lift pin plate assembly 420 is extended to place the clamp assembly 140 in the open position, a substrate 122 can be removed from or placed within the clamp assembly 140. When a substrate 122 is positioned within the clamp assembly 140 in the open position, it is supported by the plurality of lift pins 402. According to some embodiments, if the substrate 122 is positioned within the flipper module 130 a presence sensor 180 can be used to indicate that the substrate 122 is no longer moving and in the correct position within the clamp assembly 140. Additionally, the transfer sensor 182 can be used to indicate when the transfer robot 124 has released the substrate 122 and that the substrate 122 is only supported by the plurality of lift pins 402.

The clamp assembly 140 includes a substrate receiving region 531 disposed between a first actuation region 533 and a second actuation region 535 The substrate 122 is place in the substrate receiving region 531. The first actuation region 533 and the second actuation region 535 include mechanisms to align the substrate 122 and are mirrored so that the substrate 122 can enter the substrate receiving region 531 regardless of which of the first plate 142 or second plate 144 is disposed opposite/above the lift pin plate assembly 420.

As shown in FIG. 5A and FIG. 5B, the clamp assembly 140 includes the substrate receiving region 531. In some embodiments, one or more alignment mechanisms 590 include is a first alignment mechanism 590. A second alignment mechanism 590 is a mirror mechanism of the first alignment mechanism 590 and is disposed across the substrate receiving region 531 from the first alignment mechanism 590 (FIG. 5A). The one or more alignment mechanisms 590 maybe any of the alignment mechanisms 600, 700, 800, 900 described below. The substrate receiving region 531 is the space defined within the clamp assembly 140 configured to receive the substrate 122. For example, the substrate receiving region 531 is the space between the spring-loaded connectors 174 (FIG. 5A).

As shown in FIG. 5B, the substrate 122 is positioned between the first and second plates 142, 144 according to some orientations. The first and second plates 142, 144 have openings that allow the plurality of substrate support elements 505a, 505b to be located within the bounds of the first and second plates 142, 144. The plurality of substrate support elements 505a, 505b, such as substrate support elements 505a, 505b illustrated in FIG. 5B, are configured to contact the substrate 122 once the clamp assembly 140 closes, as illustrated in FIG. 4. As seen in FIG. 5A, the clamp assembly 140 is held open against the bias of the spring-loaded connector 174 by the clamp assembly pins 404 that are pressing against the first plate 142. The clamp alignment pins 460 passing through the plurality of clamp alignment apertures 436a, 436b keep movement of the clamp assembly 140 limited to the first direction D1 and align the first plane P1 perpendicular to the first direction D1.

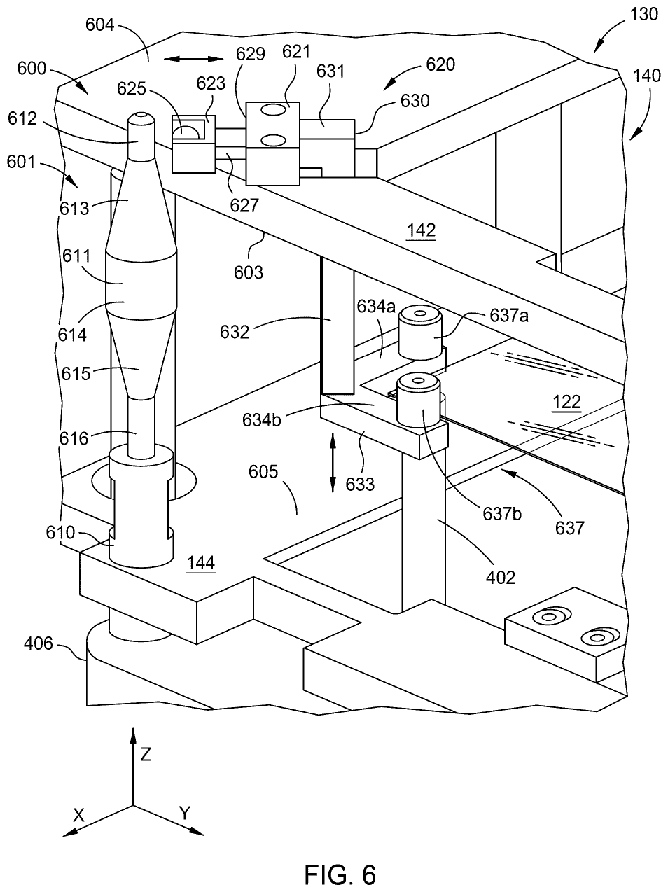

FIG. 6 is an isometric view of an alignment mechanism 600 according to some embodiments. The alignment mechanism 600 includes a profile rod 601 and a follower assembly 620. The profile rod 601 is coupled to the second plate 144 and follower assembly 620 is coupled to the first plate 142. While illustrated in this configuration, the profile rod 601 and follower assembly 620 can be coupled in the opposite configuration with the profile rod 601 coupled to the first plate 142 and follower assembly 620 coupled to the second plate 144.

The first plate 142 includes a first inner surface 603 and a first outer surface 604 disposed opposite the first inner surface 603. The second plate 144 includes a second inner surface 605 facing the first inner surface 603 of the first plate 142.

The follower assembly 620 includes a connection element 621 coupled to the first plate 142, a follower roller 625 biased toward the profile rod 601, and an arm 630 extending from the first plate 142 toward the second plate 144. The arm 630 includes one or more alignment rollers 637. The one or more alignment rollers 637 are disposed between the first plate 142 and the second plate 144.

The follower roller 625 is biased toward the profile rod 601 by a spring 627. The spring 627 may be a compression spring, a leaf spring, or an extension spring.

The arm 630 includes a follower member 631, a vertical member 632, and an alignment portion 633. The follower member 631 extends through a guide formed by the connection element 621 and the first plate 142. The follower member 631 has a roller housing 623 disposed opposite the vertical member 632. The roller housing 623 defines a first end of the follower member 631 and couples the follower roller 625 to the follower member 631 of the arm 630. The spring 627 biases the roller housing 623 away from the connection element 621, toward the profile rod 601. For example, the spring 627 is a compression spring disposed between the roller housing 623 and the connection element 621 and biases the follower roller 625 toward the profile rod 601.

The connection element 621 is operable to constrain the motion of the arm 630 in a linear path toward the substrate 122. The connection element 621 includes a slot 629 configured to allow the follower member 631 of the arm 630 to translate within the slot 629 as the follower roller 625 translates along a profile 611 of the profile rod 601.

The alignment portion 633 is disposed opposite the follower member 631 such that the vertical member 632 is between the alignment portion 633 and the follower member 631. In some embodiments, the alignment portion 633 includes two alignment arms 634 disposed opposite of the vertical member 632 from the follower member 631. The two alignment arms 634 include, a first alignment arm 634a and a second alignment arm 634b. In some embodiments the one or more alignment rollers 637 include a first alignment roller 637a disposed on the first alignment arm 634a and a second alignment roller 637b disposed on the second alignment arm 634b. The first alignment arm 634a is disposed between the first alignment roller 637a and the vertical member 632. The first alignment arm 634a is disposed in the same plane as the second alignment arm 634b.

The profile rod 601 includes a base 610 and the profile 611. The profile 611 includes an initial diameter 612, a first transition region 613, an alignment diameter 614, a second transition region 615, and an end diameter 616. The alignment diameter 614 is disposed between the initial diameter 612 and the end diameter 616. The alignment diameter 614 is concentric with the initial diameter 612. The first transition region 613 angles radially outward from the initial diameter 612 to the alignment diameter 614 of the profile 611.

The follower roller 625 is disposed in contact with the alignment diameter 614 of the profile rod 601 when the alignment mechanism 600 is in an alignment state. The follower roller 625 is disposed in contact with an initial diameter 612 of the profile rod 601 in a receiving state. The receiving state is when the clamp assembly 140 (FIG. 5A) is open. The alignment state is between the receiving state (FIG. 5A) and the clamped state (FIG. 4). The alignment mechanism 600 is configured to align the substrate 122 when as the alignment mechanism changes from the receiving state to the clamped state.

As the clamp assembly 140 closes onto a substrate 122, the follower roller 625 follows the profile 611. The follower roller 625 starts at the initial diameter 612 when the clamp assembly 140 is fully opened. As the clamp assembly 140 begins to close, the follower roller 625 translates along the first transition region 613 to the alignment diameter 614. Once the follower roller 625 reaches the alignment diameter 614, the clamp assembly 140 is in an alignment state. In the alignment state, the follower assembly 620 has linearly translated toward the substrate 122 and aligned the substrate 122 within the clamp assembly 140 of the flipper module 130.

As the clamp assembly 140 continues from the alignment state to the clamped state (FIG. 4), the clamp assembly 140 continues to close on the substrate 122. The follower roller 625 translates from the alignment diameter 614, along the second transition region 615, to end diameter 616. The follower assembly 620 has linearly translated away from the aligned substrate 122 and the plurality of substrate support elements 505a and 505b (FIG. 5B) hold the substrate 122 during a flip operation.

In some embodiments, the alignment mechanism 600 is a first alignment mechanism. A second alignment mechanism is a mirror mechanism of the first alignment mechanism and is disposed across a substrate receiving region 531 from the first alignment mechanism. For example, the first alignment mechanism is disposed in the first actuation region 533 and the second alignment mechanism is disposed in the second actuation region 535 (FIG. 5A). The first alignment mechanism and the second alignment mechanism are configured to actuate towards the substrate receiving region 531 when the first plate and the second plate are moved from a receiving state to a clamped state.

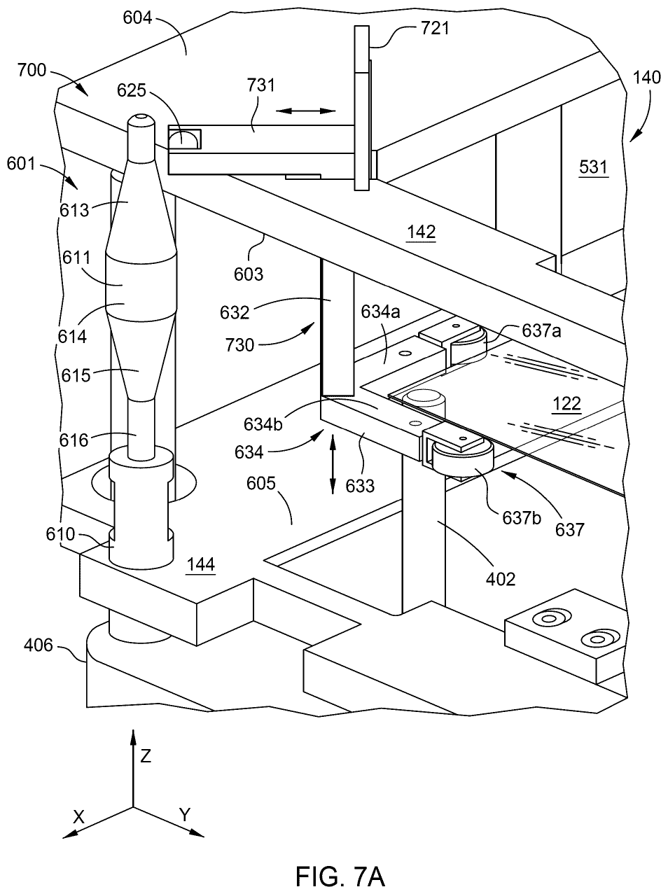

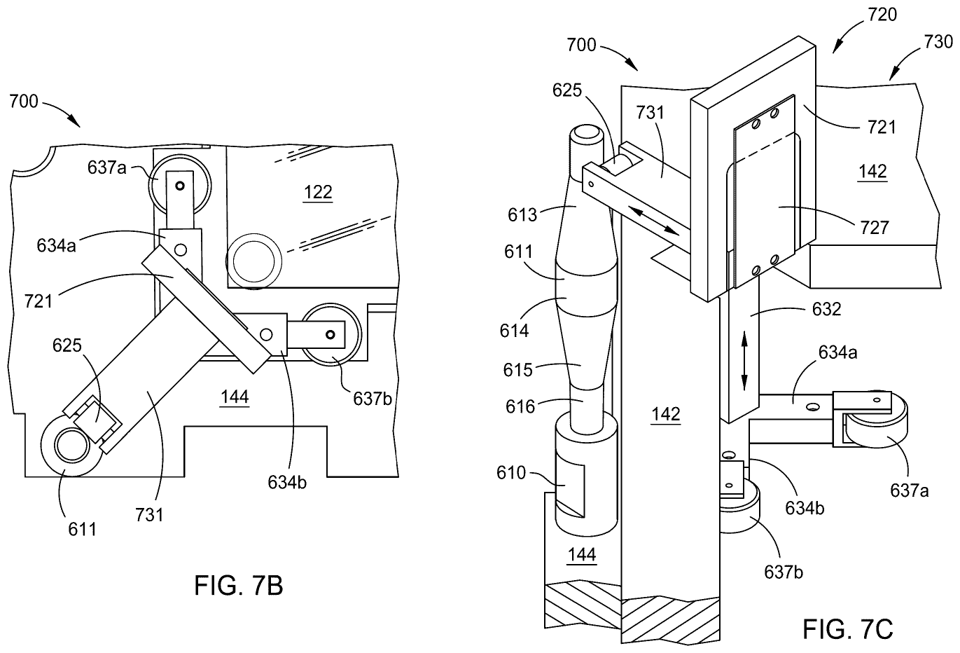

FIG. 7A is an isometric view of an alignment mechanism 700 according to some embodiments. FIG. 7B is top view of the alignment mechanism 700 according to some embodiments. FIG. 7C is an isometric view of the alignment mechanism 700 according to some embodiments. FIGS. 7A, 7B, and 7C will be described concurrently for clarity.

The alignment mechanism 700 includes the profile rod 601 and a follower assembly 720. The follower assembly 720 is similar to the follower assembly 620 of FIG. 6. The profile rod 601 is coupled to the second plate 144 and follower assembly 720 is coupled to the first plate 142. While illustrated in this configuration, the profile rod 601 and follower assembly 720 can be coupled in the opposite configuration with the profile rod 601 coupled to the first plate 142 and follower assembly 720 coupled to the second plate 144.

The follower assembly 720 includes a connection element 721 and a spring 727. The connection element 721 is coupled to the first outer surface 604 of the first plate 142. A spring 727 couples an arm 730 to the connection element 721. The arm includes a follower member 731 disposed opposite the first inner surface 603 from the first outer surface 604. The vertical member 632 is between the alignment portion 633 and the follower member 731. The spring 727 is coupled to the arm 730 proximate to where the vertical member 632 and follower member 731 merge.

The spring 727 is a leaf spring that biases the follower roller 625 toward the profile rod 601. The spring 727 allows the follower roller 625 to translate along the profile 611 of the profile rod 601. The translation of the follower roller 625 linearly translates the arm 730 towards the substrate 122 to align the substrate 122 with the flipper module 130.

In some embodiments, the alignment mechanism 700 is the first alignment mechanism. The second alignment mechanism is a mirror mechanism of the first alignment mechanism and is disposed across the substrate receiving region 531 from the first alignment mechanism. The substrate receiving region 531 is the space defined within the clamp assembly 140 configured to receive the substrate 122. The first alignment mechanism and the second alignment mechanism are configured to actuate towards the substrate receiving region 531 when the first plate and the second plate are moved from a receiving state to a clamped state.

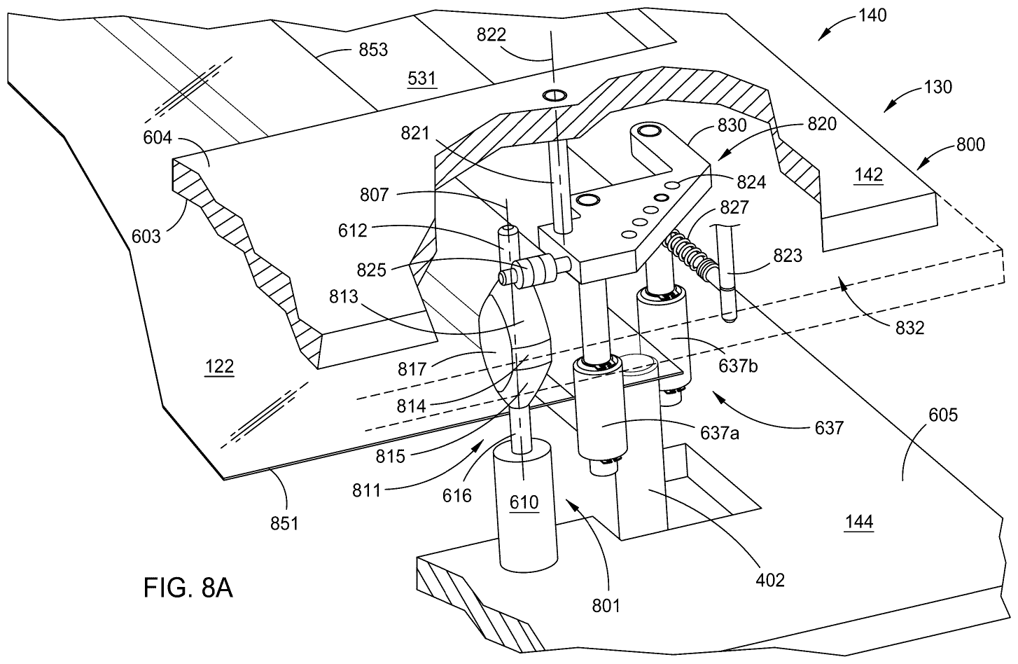

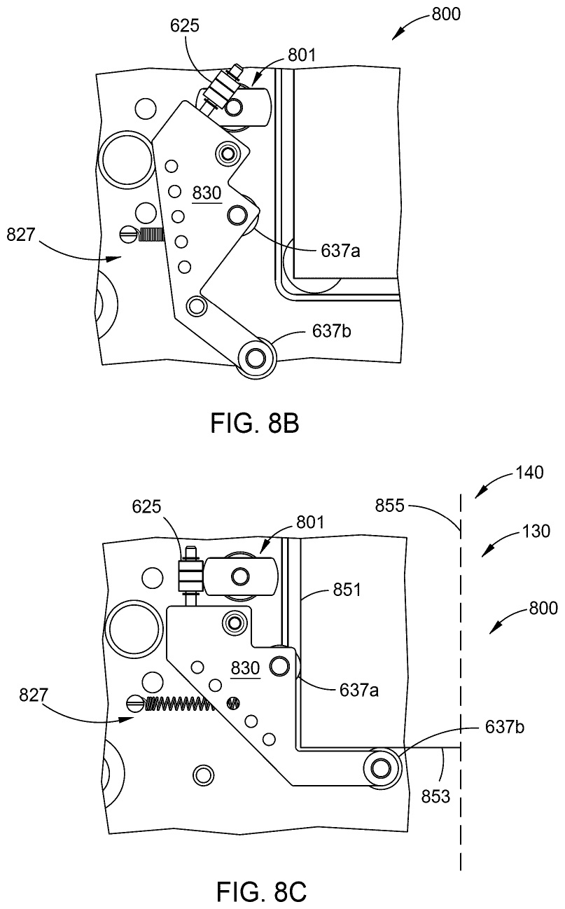

FIG. 8A is an isometric view of an alignment mechanism 800 according to some embodiments. FIG. 8B is top view of the alignment mechanism 800 according to some embodiments. FIG. 8C is top view of the alignment mechanism 800 according to some embodiments. FIGS. 8A, 8B, and 8C will be described concurrently for clarity.

The alignment mechanism 800 includes a profile rod 801 and a follower assembly 820. The profile rod 801 is coupled to the second plate 144 and extends towards the follower assembly 820 and the first plate 142. The follower assembly 820 includes a rotation plate 830, a spring pin 823, a spring 827, a spring connection 824, one or more vertical arms 832, the one or more alignment rollers 637, and a follower roller 825.

The rotation plate 830 is disposed proximate to the first inner surface 603. The rotation plate 830 is rotatably coupled to the first plate 142 by a connection element 821. The connection element 821 is a pin or rotatable shaft extending from the first plate 142 toward the second plate 144. For example, the connection element 821 is a rotatable shaft. The rotatable shaft includes a connection element axis 822 that is disposed about parallel to an axis 807 of the profile rod 801 and about parallel to the one or more vertical arms 832. In some embodiments, the one or more vertical arms 832 include a first vertical arm 832a coupled to the first alignment roller 637a and a second vertical arm 832b coupled to the second alignment roller 637b.

The spring 827 is coupled to both the spring pin 823 and the rotation plate 830. The spring 827 biases the follower roller 625 toward the profile rod 801. The spring 827 allows the follower roller 825 to translate along a profile 811 of the profile rod 801. The translation of the follower roller 625 rotatably translates rotation plate 830 about the connection element axis 822 of the connection element 821 and towards the substrate 122 to align the substrate 122 with the flipper module 130. The spring 827 biases the alignment rollers 637 away from the substrate 122 during operation (FIG. 8B).

The profile rod 801 is similar to the profile rod 601. In some embodiments, the profile rod 801 includes a surface 817. The surface 817 forms a plane paralleled to the axis 807 of the profile rod 801. The surface 817 enables the follower roller 625 to be closer to the rotation plate 830. Otherwise, an alignment diameter 814 could collide with rotation plate 830 during operation.

The spring connection 824 is where the spring 827 is connected to the rotation plate 830. The spring connection 824 is a plurality of apertures that enable the spring 827 to be pre-tensioned, allowing for tune-ability of the force applied to the substrate 122 by the alignment rollers 637.

As the clamp assembly 140 begins to close, the follower roller 625 translates from the initial diameter 612, along a first transition region 813, to the alignment diameter 814. Once the follower roller 825 reaches the alignment diameter 814, the clamp assembly 140 is in an alignment state. In the alignment state, the follower assembly 820 has rotatably translated toward the substrate 122 and aligned the substrate 122 within the clamp assembly 140 of the flipper module 130.

As the clamp assembly 140 continues from the alignment state to the clamped state (FIG. 4), the clamp assembly 140 continues to close on the substrate 122. The follower roller 625 translates from the alignment diameter 814, along the second transition region 815, to end diameter 616. The follower assembly 820 has rotated away from the aligned substrate 122 and the plurality of substrate support elements 505a and 505b (FIG. 5B) are able to hold an aligned substrate 122 during a flip operation.

As seen in FIG. 8B and FIG. 8C, during operation, the first alignment roller 637a contacts a first substrate edge 851 and the second alignment roller 637b contacts a second substrate edge 853. The first substrate edge 851 is about perpendicular to the second substrate edge 853. The clamp assembly 140 includes a loading axis 855. When the substrate 122 is loaded into the clamp assembly 140, alignment mechanism 800 aligns the substrate 122 such that one of the first substrate edge 851 or the second substrate edge 853 is perpendicular to the loading axis 855 of the clamp assembly 140 and the other of the first substrate edge 851 or the second substrate edge 853 is about parallel to the loading axis 855 of the clamp assembly 140.

In some embodiments, the alignment mechanism 800 is the first alignment mechanism. The second alignment mechanism is a mirror mechanism of the first alignment mechanism and is disposed across the loading axis 855 of the substrate receiving region 531 from the first alignment mechanism. The substrate receiving region 531 is the space defined within the clamp assembly 140 configured to receive the substrate 122. The first alignment mechanism and the second alignment mechanism are configured to actuate towards the substrate receiving region 531 when the first plate and the second plate are moved from a receiving state to a clamped state.

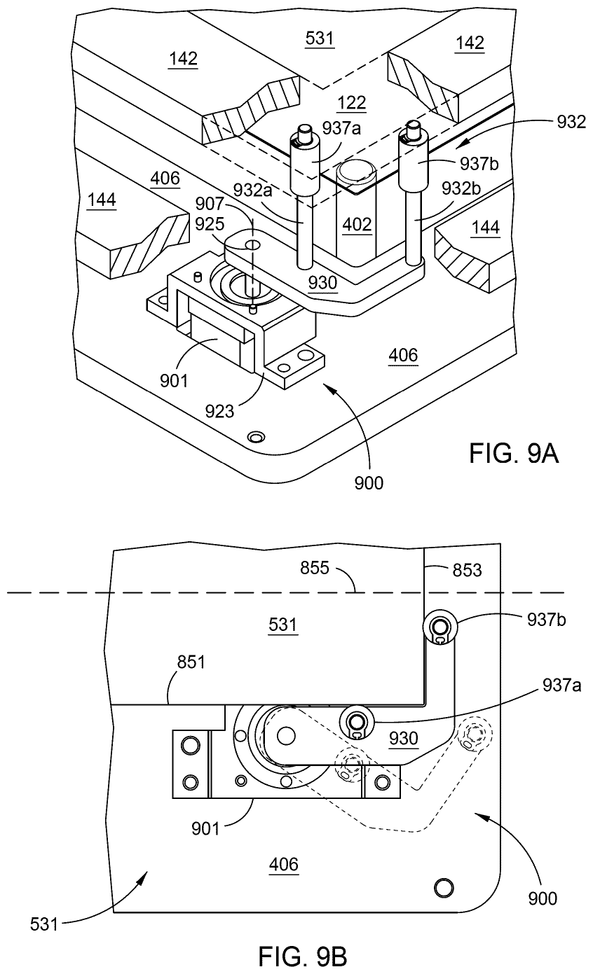

FIG. 9A is an isometric view of an alignment mechanism 900 according to some embodiments. FIG. 9B is top view of the alignment mechanism 900 according to some embodiments. FIGS. 9A and 9B will be described concurrently for clarity.

The alignment mechanism 900 includes a motor 901, a rotation plate 930 a shaft 925, and one or more vertical arms 932 extending from the lift pin plate 406 towards the clamp assembly 140. The motor 901 is coupled to the lift pin plate 406 by a motor mount 923. The rotation plate 930 is coupled to the motor 901 by the shaft 925. The shaft 925 includes an axis of rotation 907 about perpendicular to the plane of the lift pin plate 406. The one or more vertical arms 932 are coupled to the shaft 925 by the rotation plate 930. The one or more vertical arms 932 are disposed radially outward from the shaft 925. The first alignment roller 637a is disposed on a first vertical arm 932a and a second alignment roller 637b disposed on a second vertical arm 932b. The second vertical arm 932b is disposed farther from the shaft 925 than the first vertical arm 932a.

As seen in FIG. 9B, the motor 901 rotates the rotation plate 930 about the axis of rotation 907 to translate the first alignment roller 637a and the second alignment roller 637b toward the substrate 122. The first alignment roller 637a and the second alignment roller 637b align the substrate 122 with the loading axis 855 of the clamp assembly 140.

For example, the first alignment roller 637a contacts the first substrate edge 851 and the second alignment roller 637b contacts the second substrate edge 853 to translate the substrate 122 such that the first substrate edge 851 is about parallel to the loading axis 855 and the second substrate edge 853 is about perpendicular to the loading axis 855 of the clamp assembly 140.

The motor 901 an electric motor able to operate within a vacuum environment. The motor 901 is a sealed motor so as not to contaminate the vacuum environment within the housing 131 (FIG. 4). By having an electronically controlled motor the alignment can be independent of a profile rod.

FIG. 2 illustrates a method of flipping a substrate. At operation 202, as seen in FIG. 3B, the substrate 122 is transferred from the transfer chamber 106 into the flipper module 130. During operation 202, the process system 100 moves the substrate 122 into a position for the clamp assembly 140 to receive the substrate 122 (FIG. 3A).

Operation 204 begins with the clamp assembly 140 in the open position, as seen in FIG. 5A. The substrate is received on the plurality of lift pins 402 because the lift pin plate assembly 420 is positioned to contact the clamp assembly 140 and hold it open.

At operation 206, the substrate 122 is aligned by an alignment mechanism. For example, the clamp assembly 140 includes four alignment mechanisms disposed in the four corners of the clamp assembly 140. Each alignment mechanism of the four alignment mechanisms may be the alignment mechanism 600, the alignment mechanism 700, the alignment mechanism 800, or the alignment mechanism 900. The alignment mechanisms align the substrate 122 within the clamp assembly 140.

At operation 208, the lift pin plate 406 has been lowered out of the way of the clamp assembly's rotation. The clamp assembly 140 is rotated by about 180°by the motor 133. The orientation of the clamp assembly 140 and the substrate 122 secured therein is then considered to be “flipped” after the clamp assembly 140 is rotated by about 180°.

At operation 210, after rotation, the front side 122a of the substrate 122 is oriented downward and the backside 122b of the substrate 122 is oriented upward. The front side 122a remains in contact with the substrate support elements 505a of the first clamp assembly 148a, and the backside 122b remains in contact with the substrate support elements 505b of the second clamp assembly 148b during rotation because the clamp assembly 140 remains closed around the substrate 122 due to the bias applied by the spring-loaded connectors 174. The clamp assembly 140 stops rotation once the back stop assembly plate 150 come in contact with a backstop 450. In other embodiments, rotation determination methods may include an encoder attached to the motor 133 and a sensor to indicate a desired rotation has been reached the lift pin plate 406 is raised once again to open the clamp assembly 140 to resemble to orientation shown in FIG. 5A. However, at operation 210, the first plate 142 and the second plate 144 have switched locations so that the second plate 144 is positioned over the first plate 142. The actuator 135 extends the lift pin plate assembly 420 to contact the clamp assembly 140 and hold it open by the clamp assembly pins 404 contacting the plate 142, 144 opposite the lift pin plate assembly 420. The plurality of clamp assembly pins 404 pass through apertures 432a, 434a within the first plate 142 to contact the second plate 144. The plurality of spring-loaded connectors 174 no longer secure the substrate 122 within the clamp assembly 140 and the substrate 122 rests on the lift pins 402. The clamp assembly 140 includes the backstop 450 to stop rotation.

At operation 210, the substrate 122 is transferred out of the flipper module 130. The transfer out of the flipper module may be by use of the transfer robot 124 but other means are contemplated. According to some embodiments, the transfer robot 124 removes a flipped substrate 122 from the lift pins 402 and flipper module 130, and transfers the flipped substrate 122 into a transfer chamber 106. When the substrate 122 is transferred back into the transfer chamber 106 after being flipped, the preclean and/or deposition processes can be performed on the unprocessed side of the substrate. As described above, the substrate 122 is maintained in vacuum during each operation of the method 200. Therefore, when the substrate 122 is transferred back into the transfer chamber 106, there is no need for degassing of the substrate 122 prior to performing subsequent preclean and/or deposition processes on the backside 122b. This results in a significant time savings and increased throughput for dual sided processing.

While the foregoing is directed to embodiments of the present disclosure, other and further embodiments of the disclosure may be devised without departing from the basic scope thereof, and the scope thereof is determined by the claims that follow.

What is claimed is:

1. A module of a processing system, comprising:
a clamp assembly comprising:
a first plate;
a second plate disposed about parallel to the first plate; and
an alignment mechanism comprising:
a profile rod coupled to the second plate; and
a follower assembly coupled to the first plate, the follower assembly comprising:
a connection element coupled to the first plate;
a follower roller biased toward the profile rod; and
an arm extending from the first plate toward the second plate, the arm comprising an alignment roller disposed between the first plate and the second plate.

2. The module of claim 1, wherein the follower roller is biased by a compression spring, a leaf spring, or an extension spring.

3. The module of claim 1, wherein the arm of the follower assembly further comprises:
a vertical member;
a follower member extending from the vertical member to the follower roller disposed on a first end of the follower member; and
an alignment arm disposed opposite of the vertical member from the follower member, the alignment arm disposed between the vertical member and the alignment roller.

4. The module of claim 3, wherein the alignment arm is a first alignment arm, the alignment roller is a first alignment roller and the arm of the follower assembly further comprises:
a second alignment arm disposed in a same plane as the first alignment arm; and
a second alignment roller, the second alignment roller parallel to the first alignment roller.

5. The module of claim 1, wherein the profile rod comprises:
an initial diameter; and
an alignment diameter concentric with the initial diameter, the profile rod angling from the initial diameter toward the alignment diameter.

6. The module of claim 1, wherein:
the follower roller is in contact with an alignment diameter of the profile rod when in an alignment state; and
the follower roller is in contact with an initial diameter of the profile rod in a receiving state.

7. The module of claim 1, wherein the follower assembly further comprises:
a rotation plate coupled to the first plate by the connection element, the connection element being a rotatable shaft, the rotation plate disposed proximate a first inner surface of the first plate, the rotation plate coupled to the alignment roller by the arm.

8. The module of claim 1, wherein the connection element comprises a slot configured to allow the arm to translate within the slot as the follower roller translates along the profile rod.

9. The module of claim 1, wherein the connection element is coupled to the arm by a leaf spring configured to translate the arm along the profile rod.

10. A flipper module comprising:
a clamp assembly comprising:
a first plate;
a second plate disposed about parallel to the first plate, wherein the first plate and the second plate define a substrate receiving region therebetween;
a flipping axis disposed between the first plate and the second plate, the clamp assembly configured to rotate about the flipping axis;
a first alignment mechanism comprising:
a profile rod coupled to the second plate and extending toward the first plate; and
a follower assembly coupled to the first plate, the follower assembly comprising:
a connection element coupled to the second plate;
a follower roller biased toward the profile rod; and
an arm extending past a first outer surface of the first plate and extending toward the second plate, the arm comprising an alignment roller disposed between the first plate and the second plate, the first alignment mechanism configured to actuate towards the substrate receiving region when the first plate and the second plate are moved from a receiving state to a clamped state.

11. The flipper module of claim 10, wherein the first alignment mechanism is configured to align a substrate as the first alignment mechanism changes from the receiving state to the clamped state.

12. The flipper module of claim 10, wherein the first alignment mechanism translates the arm along a linear path when changing from the receiving state to the clamped state.

13. The flipper module of claim 10, wherein the first alignment mechanism rotates the arm about a connection element axis when changing from the receiving state to the clamped state.

14. The flipper module of claim 10, wherein the first alignment mechanism is disposed in a first actuation region of the substrate receiving region and a second alignment mechanism is disposed in a second actuation region of the substrate receiving region opposite the first actuation region.

15. The flipper module of claim 10, wherein the alignment roller is a first alignment roller and the arm of the first alignment mechanism comprises:
a vertical member;
a follower member extending from the vertical member to the follower roller disposed on a first end of the follower member; and
two alignment arms disposed opposite of the vertical member from the follower member, the two alignment arms comprising:
a first alignment arm coupled to the first alignment roller; and
a second alignment arm coupled to a second alignment roller, the second alignment arm disposed perpendicular to the first alignment arm.

16. The flipper module of claim 15, wherein the first alignment roller and the second alignment roller are about parallel to the vertical member.

17. The flipper module of claim 10, wherein the follower assembly of the first alignment mechanism further comprises:
a rotation plate rotatably coupled to the first plate by the connection element, the rotation plate disposed proximate a first inner surface of the first plate, the rotation plate coupled to the alignment roller by the arm.

18. A module comprising:
a clamp assembly comprising:
a receiving region separating a first actuation region and a second actuation region;
a lift pin plate assembly comprising:
a lift pin plate;
a plurality of lift pins that extend toward the clamp assembly; and
one or more alignment mechanisms, each alignment mechanism of the one or more alignment mechanisms comprising:
a motor coupled to the lift pin plate;
a shaft disposed perpendicular to the lift pin plate;
a rotation plate extending from the shaft;
a first arm extending from the rotation plate and away from the motor; and
a second arm extending from the rotation plate and away from the motor,.

19. The module of claim 18, wherein the one or more alignment mechanisms comprise:
a first alignment mechanism; and
a second alignment mechanism disposed opposite the receiving region from the first alignment mechanism.

20. The module of claim 18, wherein each of the one or more alignment mechanisms rotate the rotation plate from a first state toward a lift pin when in a second state.
